(19) United States
(12) Patent Application Publication
(10) Pub. No.: US 2012/0018813 A1
(43) Pub. Date: Jan. 26, 2012

(54) BARRIER COAT FOR ELIMINATION OF RESIST RESIDUES ON HIGH k/METAL GATE STACKS

(75) Inventors: Steven J. Holmes, Guilderland, NY (US); Hemanth Jagannathan, Guilderland, NY (US); Hiroshi Sunamura, Albany, NY (US); Junli Wang, Slingerlands, NY (US)

(73) Assignee: INTERNATIONAL BUSINESS MACHINES CORPORATION, Armonk, NY (US)

(21) Appl. No.: 12/841,312

(22) Filed: Jul. 22, 2010

(51) Int. Cl. H01L 27/088; H01L 21/28

(52) U.S. Cl. 257/392; 438/591; 257/E21.19; 257/E27.061

(57) ABSTRACT

A technique for substantially eliminating resist residues from a gate stack that includes, from bottom to top, a high k gate dielectric and a metal gate, e.g., a high k/metal gate stack, is provided. In particular and in one embodiment, a method is disclosed in which a patterned resist and optionally a patterned barrier coating are formed atop a surface of the metal gate electrode of a high k/metal gate stack prior to patterning the metal gate electrode. At least the metal gate electrode not protected by the patterned material is then etched. The presence of the barrier coating eliminates resist residues from the resultant gate stack. The technique provided can be used in fabricating planar semiconductor devices such as, for example, metal oxide semiconductor field effect transistors (MOSFETS) including complementary metal oxide semiconductor (CMOS) field effect transistors, as well as non-planar semiconductor devices such as, for example, finFETs.

The present disclosure relates to semiconductor structures and methods of fabricating the same. More particularly, the present disclosure provides a barrier coating for semiconductor structures that include a gate stack of, from bottom to top, a high dielectric constant (k) dielectric and a metal gate electrode, in which the barrier coating substantially eliminates resist residue during the gate stack patterning process.

In current complementary metal oxide semiconductor (CMOS) technology, a polysilicon gate is typically employed. One disadvantage of utilizing polysilicon gates is that at inversion the polysilicon gates generally experience depletion of carriers in the area of the polysilicon gate that is adjacent to the gate dielectric. This depletion of carriers is referred to in the art as the polysilicon depletion effect. The polysilicon depletion effect reduces the effective gate capacitance of the CMOS device. Ideally, it is desirable that the gate capacitance of the CMOS device be high since high gate capacitance typically equates to more charge being accumulated in the inversion layer. As more charge is accumulated in the channel, the source/drain current becomes higher when the transistor is biased.

CMOS devices including a gate stack comprising a bottom polysilicon portion and a top silicide portion are also known. The layer of silicide in such a gate stack contributes to a decrease in the resistance of the gate. The decrease in resistance causes a decrease in the RC time propagation delay of the gate. Although a silicide top gate region may help decrease the resistance of the transistor, charge is still depleted in the vicinity of the interface formed between the bottom polysilicon gate and gate dielectric, thereby causing a smaller effective gate capacitance.

Another type of CMOS device that is available is one where the gate electrode includes at least one metal layer that is located on an upper surface of a high k gate dielectric, e.g., a high k/metal gate stack. Although such metal-gated devices address the depletion problem mentioned above in regard to polysilicon gates, there are some problems associated with fabricating high k/metal gate stacks. For example, the patterning of high k/metal gate stacks is a crucial step in complementary metal oxide semiconductor (CMOS) processing. However, severe resist residues and resist adhesion failure have been observed on high k/metal gate stacks due to the interaction between a conductive metal such as, for example, TiN and the overlying resist. These problems are present in planar semiconductor devices as well as non-planar semiconductor devices, but are typically more severe over the topography of a non-planar semiconductor device such as, for example, a finFET device.

In a typical finFET device, at least one horizontal channel is provided within the vertical sidewalls of a semiconductor “fin” that is present upon a substrate. Typically, the fin comprises a single crystalline semiconductor material with a substantially rectangular cross-sectional area. The height of the fin is typically greater than the width of the fin to enable higher on-current per unit area of semiconductor area used for the finFET structure. In order to obtain desirable control of short channel effects (SCEs), the semiconductor fin is thin enough in a device channel region to ensure forming fully depleted semiconductor devices. Typically, the thickness, or the horizontal width, of a fin in a finFET is less than two-thirds of its gate length in order to obtain good control of the short channel effects.

An inverted U-shaped gate electrode often straddles a central section of the semiconductor fin and covers the gate dielectric layer. In a typical finFET, a gate dielectric layer and a gate conductor are located upon each of the two semiconductor fin sidewalls facing each other thereby forming a double gated device. A hard mask of substantial thickness is typically located between the top surface of the fin and the top portion of the inverted U-shaped gate electrode such that the top surface of the fin is not controlled directly by the portion of the gate electrode above it. In a typical triple gate FET, a gate electrode of an inverted U shape is typically located upon the two semiconductor fin sidewalls and also upon the top surface of the fin structure. The top surface of the fin is separated from the top portion of the gate electrode only by a gate dielectric layer and is thus controlled by the gate electrode. Doping is performed by techniques such as ion implantation or dopant diffusion on the source and drain regions, which are the end portions of the semiconductor fin, to deliver halo, extension, and source/drain doping while using the gate electrode or other masking layer as a mask on the channel region of the device.

### SUMMARY

The present disclosure provides a technique for substantially eliminating resist residues from a gate stack that includes, from bottom to top, a high k gate dielectric and a metal gate electrode, e.g., a high k/metal gate stack. In particular, the present disclosure provides a method in which a barrier coating material is formed atop a surface of a metal gate electrode of a high k/metal gate stack prior to patterning the metal gate electrode. A photoresist material is then applied atop the barrier coating material and thereafter at least the photoresist material is patterned into a patterned resist. In one embodiment, only the photoresist material is patterned. In another embodiment, both the photoresist material and the barrier coating material are patterned. An exposed portion of either the metal gate electrode itself, or a material stack of the barrier coating material and the metal gate electrode is then etched utilizing at least the patterned photoresist as an etch mask. In some embodiments, both the patterned photoresist and the patterned barrier coating are employed as an etch mask. The presence of the barrier coating (patterned or non-patterned) eliminates resist residues from the resultant patterned gate stack. The technique provided in the present disclosure can be used in fabricating planar semiconductor devices such as, for example, metal oxide semiconductor field effect transistors (MOSFETS) including complementary metal oxide semiconductor (CMOS) field effect transistors, as well as non-planar semiconductor devices such as, for example, finFETs.

In one embodiment, a method is provided that includes forming a gate dielectric having a dielectric constant that is greater than silicon oxide on at least one surface of a semiconductor substrate. A metal gate electrode is formed atop the gate dielectric and thereafter a material stack including, from bottom to top, a barrier coating material and a photoresist material is formed atop the metal gate electrode. In one embodiment, both the photoresist material and the barrier coating material of the material stack are patterned by lithography and etching providing a patterned material stack including a patterned barrier coating and a patterned resist atop the metal gate electrode. In another embodiment, only the photoresist material of the material stack is patterned by lithography providing a patterned resist atop a non-patterned barrier coating material; the non-patterned barrier coating material in turn is located atop the metal gate electrode. In one embodiment, an exposed portion of the metal gate electrode, not protected by at least the patterned photoresist and the patterned barrier coating is then removed by etching providing a patterned metal gate electrode. In another embodiment, an exposed portion of the barrier coating material and the underlying metal gate electrode, not protected by the patterned photoresist material, are then removed by etching providing a patterned metal gate electrode. In some embodiments, the patterned barrier coating can remain atop the patterned gate electrode, while in other embodiments, the patterned barrier coating is removed from the structure.

The method described above provides a semiconductor structure including at least one patterned high k/metal gate stack in which resist residues have been eliminated from the patterned high k/metal gate stack.

In one embodiment, the gate dielectric is formed on a planar upper surface of a semiconductor substrate. In another embodiment, the gate dielectric is formed on a semiconductor fin that extends from a surface of a semiconductor substrate.

In one embodiment, a single patterned high k/metal gate stack is provided. In another embodiment, a plurality of patterned high k/metal gate stacks is provided. When a plurality of patterned high k/metal gate stacks is formed, the gate stacks can have the same or different polarity, i.e., n-type (planar and/or non-planar) semiconductor devices and/or p-type (planar and/or non-planar) semiconductor devices.

The present disclosure also provides a method of forming complementary metal oxide semiconductor structures that includes providing a semiconductor substrate having a first device region and a second device region. A gate dielectric having a dielectric constant that is greater than silicon oxide is formed on at least one surface of the semiconductor substrate in both device regions. A first metal gate electrode is formed atop the gate dielectric in both device regions and thereafter a material stack including, from bottom to top, a barrier coating material and a photoresist material is formed atop the first metal gate electrode. In one embodiment, both the photoresist material and the barrier coating material of the material stack are then patterned by lithography and etching providing a patterned material stack including a patterned barrier coating and a patterned resist atop the first metal gate electrode in one of the device regions. In another embodiment, only the photoresist material of the material stack is patterned by lithography providing a patterned resist in one device region that is located atop a portion of the non-patterned barrier coating material. In one embodiment, the exposed portion of the first metal gate electrode in the other device region, not protected by the patterned resist and the patterned barrier coating, is then removed by etching providing a patterned first metal gate electrode in the one device region. In another embodiment, the exposed portion of the barrier coating material and the underlying first metal gate electrode in the other device region, not protected by the patterned resist, are then removed by etching providing a patterned barrier coating and a patterned first metal gate electrode in the one device region. After patterning the first metal gate electrode, and in some instances, the patterned barrier coating can be removed from the structure. A second metal gate electrode is formed in both device regions, wherein a first portion of the second metal gate electrode is present atop the first metal gate electrode or, if present, the patterned barrier coating material in the one device region and a second portion of the second metal gate electrode is present atop the gate dielectric in the other device region.

The method described above provides a semiconductor structure including at least one patterned high k/metal gate stack in which resist residues have been eliminated from the patterned high k/metal gate stack. In one embodiment, the gate dielectric is formed on a planar upper surface of a semiconductor substrate. In another embodiment, the gate dielectric is formed on a semiconductor fin that extends from a surface of a semiconductor substrate.

The present disclosure also provides a method of forming complementary metal oxide semiconductor finFET structures that includes providing a semiconductor substrate having a first device region and a second device region. At least one semiconductor fin is then formed in each of the device regions. A gate dielectric having a dielectric constant that is greater than silicon oxide is formed on at least sidewalls of each semiconductor fin in both device regions. A first metal gate electrode is formed atop the gate dielectric in both device regions and thereafter a material stack including, from bottom to top, a barrier coating material and a photoresist material is formed atop the first metal gate electrode. In one embodiment, both the photoresist material and the barrier coating material of the material stack are then patterned by lithography and etching providing a patterned material stack including a patterned barrier coating and a patterned resist atop the first metal gate electrode in one of the device regions. In another embodiment, only the photoresist material of the material stack is patterned by lithography providing a patterned resist atop the barrier coating material which, in turn, is located atop the first metal gate electrode in one of the device regions. In one embodiment, the exposed portion of the first metal gate electrode in the other device region, not protected by at least the patterned resist and patterned barrier coating, is then removed by etching providing a patterned first metal gate electrode in the one device region. In another embodiment, the exposed portion of the barrier coating material and the underlying first metal gate electrode in the other device region, not protected by the patterned resist, are then removed by etching providing a patterned barrier coating and a patterned first metal gate electrode in the one device region. After patterning the first metal gate electrode, and in some embodiments, the patterned barrier coating is removed from the one device region. A second metal gate electrode is formed in both device regions, wherein a first portion of the second metal gate electrode is present atop either the first metal gate electrode or, if present, the patterned barrier coating in the one device region and a second portion of the second metal gate electrode is present atop the gate dielectric in the other device region.

In another aspect, a semiconductor structure is provided that includes a semiconductor substrate having at least one patterned gate stack located on a surface thereof, wherein the at least one patterned gate stack includes, from bottom to top, a high k gate dielectric and a metal gate electrode, and wherein the at least one patterned gate stack is free of resist residues. By “free of resist residues” it is meant there is no visible detection of resist residues in the area in which the photoresist is exposed during the lithographic process. The visible detection can be determined by viewing the SEM images as shown, for example, in FIG. 8 of the present application.

In one embodiment of the present disclosure, the semiconductor substrate includes at least one semiconductor fin in which the gate dielectric is present on at least sidewalls thereof.

In another embodiment of the present disclosure, the semiconductor substrate includes a first device region and a second device region, wherein the at least one patterned gate stack comprises at least one first patterned gate stack including, from bottom to top, a first portion of a gate dielectric material, a first metal gate electrode, and a first portion of a second metal gate electrode present in one of the device regions, and at least one second patterned gate stack including, from bottom to top, a second portion of the gate dielectric material, and a second portion of the second metal gate electrode present in the other device region, and wherein each of the patterned gate stacks is free of resist residues.

### BRIEF DESCRIPTION OF THE DRAWINGS

FIG. 1 is a pictorial representation (though a cross sectional view) depicting an initial structure including a semiconductor substrate having a first device region and a second device region and an overlying hard mask that can be employed in one embodiment of the present disclosure.

FIG. 2 is a pictorial representation (through a cross sectional view) depicting the initial structure of FIG. 1 after forming at least one semiconductor fin in the first device region and in the second device region.

FIG. 3 is a pictorial representation (through a cross sectional view) depicting the structure of FIG. 2 after forming a high k gate dielectric, a first threshold voltage adjusting layer, and a first metal gate electrode in both device regions.

FIG. 4A is a pictorial representation (through a cross sectional view) depicting the structure of FIG. 3 after forming a patterned material stack including a patterned resist and a patterned barrier coating in one of the device regions, while leaving the other device region exposed, in accordance with one embodiment of the present disclosure.

FIG. 4B is a pictorial representation (through a cross sectional view) depicting the structure of FIG. 3 after forming a patterned photoresist in one of the device regions, while leaving the other device region exposed; in this embodiment the barrier coating material is present in both device regions, i.e., the barrier coating material is not patterned at this stage of the process.

FIG. 5 is a pictorial representation (though a cross sectional view) depicting the structure of FIG. 4A or FIG. 4B after removing the barrier coating material, if present, the first metal gate electrode and the underlying first threshold voltage adjusting layer in the one device region that is not protected by the patterned resist.

FIG. 6 is a pictorial representation (through a cross sectional view) depicting the structure of FIG. 5 after forming at least a second metal gate electrode in both device regions.

FIG. 7 is a SEM of a prior art high k/metal gate stack that has been processed utilizing a prior art processing flow, i.e., without the use of the barrier coating disclosed herein.

FIG. 8 is a SEM of a high k/metal gate stack that has been processed utilizing the processing flow of the present disclosure, i.e., with the use of the barrier coating disclosed herein.

### DETAILED DESCRIPTION

The present disclosure, which provides a barrier coat for the elimination of resist residues on high k/metal gate stacks, will now be described in greater detail by referring to the following discussion and drawings that accompany the present application. It is noted that the drawings are provided for illustrative purposes only and are not drawn to scale.

In the following description, numerous specific details are set forth, such as particular structures, components, materials, dimensions, processing steps and techniques, in order to illustrate the present disclosure. However, it will be appreciated by one of ordinary skill in the art that various embodiments of the present disclosure may be practiced without these, or with other, specific details. In other instances, well-known structures or processing steps have not been described in detail in order to avoid obscuring the various embodiments of the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, a method is provided that includes forming a gate dielectric having a dielectric constant that is greater than silicon oxide on at least one surface of a semiconductor substrate. A metal gate electrode is formed atop the gate dielectric and thereafter a material stack including, from bottom to top, a barrier coating material and a photoresist material is formed atop the metal gate electrode. In one embodiment, both the photoresist material and the barrier coating material of the material stack are then patterned by lithography and etching providing a patterned material stack including a patterned barrier coating and a patterned resist atop the first metal gate electrode in one of the device regions. In another embodiment, only the photoresist material of the material stack is patterned by lithography providing a patterned resist in one device region that is located atop a portion of the non-patterned barrier coating material. In one embodiment, the exposed portion of the first metal gate electrode in the other device region, not protected by the patterned resist and the patterned barrier coating, is then removed by etching providing a patterned first metal gate electrode in the one device region. In another embodiment, the exposed portion of the barrier coating material and the underlying first metal gate electrode in the other device region, not protected by the patterned resist, are then removed by etching providing a patterned barrier coating and a patterned first metal gate electrode in the one device region. After patterning the first metal gate electrode, and in some instances, the patterned barrier coating can be removed from the structure. A second metal gate electrode is formed in both device regions, wherein a first portion of the second metal gate electrode is present atop the first metal gate electrode or, if present, the patterned barrier coating material in the one device region and a second portion of the second metal gate electrode is present atop the gate dielectric in the other device region.

In one embodiment, the gate dielectric is formed on a planar upper surface of a semiconductor substrate. In another embodiment, the gate dielectric is formed on a semiconductor fin that extends from a surface of a semiconductor substrate.

In one embodiment, a single patterned high k/metal gate stack is provided. In another embodiment, a plurality of patterned high k/metal gate stacks is provided. When a plurality of patterned high k/metal gate stacks is formed, the gate stacks can have the same or different polarity.

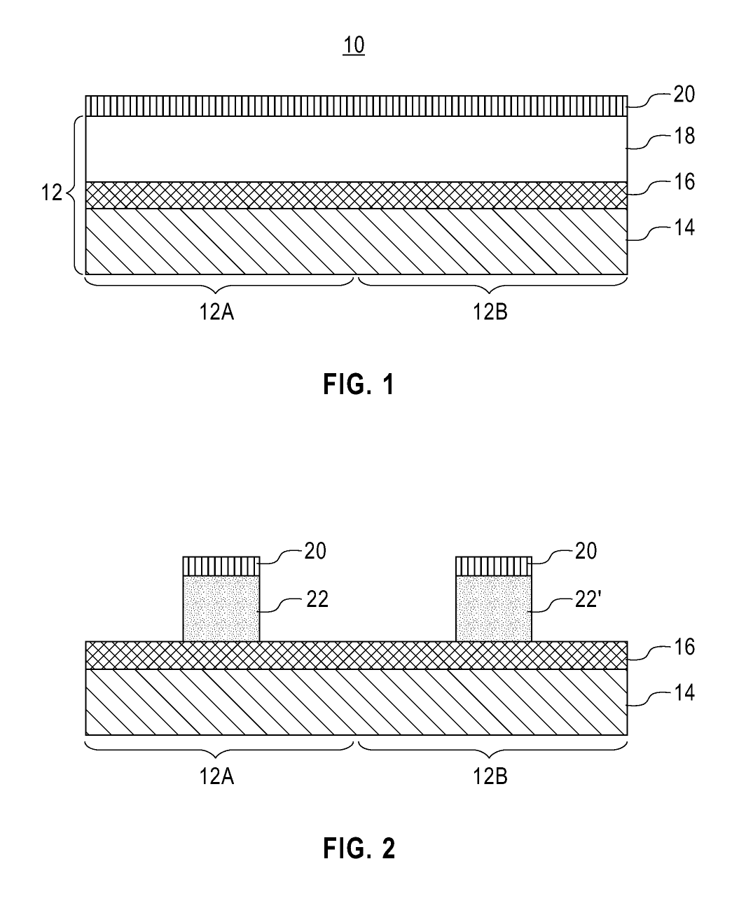

Reference is now made to FIGS. 1-6 which illustrate an embodiment of the present disclosure in which finFET structures are formed. Although finFET structures are specifically described and illustrated, the present disclosure can also be employed in making other non-planar semiconductor devices as well as planar semiconductor devices. It is also noted that the present disclosure is not limited to forming different conductivity type devices, but can be used in for forming the same conductivity devices on a surface of a semiconductor substrate.

The specific embodiment that is described and illustrated begins by providing the initial structure 10 shown in FIG. 1. Specifically, the initial structure 10 includes a semiconductor substrate 12 having a hard mask 20 located on an upper surface thereof. The semiconductor substrate 12 includes a first device region 12A and a second device region 12B. The first device region 12A can be a device region in which either an nfinFET structure or a pfinFET structure is to be subsequently formed, while the second device region 12B is the device region in which the other of the nfinFET structure or the pfinFET structure, not present in the first device region 12A, is to be subsequently formed. In the specific embodiment shown in the drawings, the first device region 12A is the nfinFET device region, while the second device region 12B is the pfinFET device region.

In one embodiment, and as shown in the drawings, the semiconductor substrate 12 includes a semiconductor-on-insulator substrate (SOI). In another embodiment (not shown), the semiconductor substrate 12 is a bulk semiconductor material.

When an SOI substrate is employed, the SOI substrate includes a handle substrate 14, a buried insulating layer 16 located on an upper surface of the handle substrate 14, and a semiconductor layer 18 located on an upper surface of the buried insulating layer 16.

The handle substrate 14 and the semiconductor layer 18 may comprise the same, or different, semiconductor material. The term “semiconductor” as used herein in connection with the semiconductor material of the handle substrate 14 and the semiconductor layer 18 denotes any semiconducting material including, for example, Si, Ge, SiGe, SiC, SiGeC, InAs, GaAs, InP or other like III/V compound semiconductors. Multilayers of these semiconductor materials can also be used as the semiconductor material of the handle substrate 14 and the semiconductor layer 18. In one embodiment, the handle substrate 14 and the semiconductor layer 18 are both comprised of Si. In another embodiment, hybrid SOI substrates are employed which have different surface regions of different crystallographic orientations.

The handle substrate 14 and the semiconductor layer 18 may have the same or different crystal orientation. For example, the crystal orientation of the handle substrate 14 and/or the semiconductor layer 18 may be {100}, {110}, or {111}. Other crystallographic orientations besides those specifically mentioned can also be used in the present disclosure. The handle substrate 14 and/or the semiconductor layer 18 of the SOI substrate may be a single crystalline semiconductor material, a polycrystalline material, or an amorphous material. Typically, at least the semiconductor layer 18 is a single crystalline semiconductor material.

The buried insulating layer 16 of the SOI substrate may be a crystalline or non-crystalline oxide or nitride. In one embodiment, the buried insulating layer 16 is an oxide. The buried insulating layer 16 may be continuous, as shown, or it may be discontinuous. When a discontinuous buried insulating region is present, the insulating region exists as an isolated island that is surrounded by semiconductor material.

The SOI substrate may be formed utilizing standard processes including for example, SIMOX (separation by ion implantation of oxygen) or layer transfer. When a layer transfer process is employed, an optional thinning step may follow the bonding of two semiconductor wafers together. The optional thinning step reduces the thickness of the semiconductor layer 18 to a layer having a thickness that is more desirable.

The thickness of the semiconductor layer 18 of the SOI substrate is typically from 100 Å to 1000 Å, with a thickness from 500 Å to 700 Å being more typical. If the thickness of the semiconductor layer 18 is not within the above mentioned range, a thinning step such as, for example, planarization or etching can be used to reduce the thickness of the semiconductor layer 18 to a value within the range mentioned above. If thinning is to be employed, it is performed prior to forming the hard mask 20 on an upper surface of semiconductor substrate 12, i.e., an upper surface of the semiconductor layer 18.

The buried insulating layer 16 of the SOI substrate typically has a thickness from 10 Å to 2000 Å, with a thickness from 1000 Å to 1500 Å being more typical. The thickness of the handle substrate 14 of the SOI substrate is inconsequential to the present disclosure.

FIG. 1 also shows the presence of a hard mask 20 on an uppermost surface of the semiconductor substrate 12. The hard mask 20 can be formed utilizing a conventional deposition process such as, for example, chemical vapor deposition (CVD), plasma enhanced chemical vapor deposition (PECVD), chemical solution deposition, evaporation or other like deposition processes. Alternatively, the hard mask 20 can be formed by a thermal process such as, for example, oxidation or nitridation. Any combination of the above mentioned processes can also be used in forming the hard mask 20.

The hard mask 20 can comprise an oxide, nitride, oxynitride or any combination thereof including multilayers. In one embodiment, the hard mask 20 is an oxide including, for example, silicon oxide or silicon nitride. The thickness of the hard mask 20 may vary depending on the technique used in forming the same, the material of the hard mask itself, and the number of layers within the hard mask layer. Typically, the hard mask 20 has a thickness from 200 Å to 800 Å, with a thickness from 400 Å to 600 Å being more typical.

Referring now to FIG. 2, there is shown the structure of FIG. 1 after forming at least one parallel oriented semiconducting body in each of the device regions (i.e., first device region 12A, and second device region 12B). Each of the semiconductor bodies that are formed extends from a surface of the semiconductor substrate 12. It is noted that each of the parallel oriented semiconducting bodies thus formed has a narrow width on the order of 20 nm or less and, a vertical thickness that is within the range provided above. As such, the semiconducting bodies that are formed are referred hereinafter as semiconductor fins. The plurality of semiconductor fins may be used as semiconductor bodies for nfinFET devices and pfinFET devices. In the drawings, the semiconductor fin designated as 22 is used as a semiconductor body for an nfinFET device, while the semiconductor fin designated as 22′ is used as a semiconductor body for a pfinFET device.

Each of the semiconductor fins 22, 22′ can be formed by lithography and etching. The lithographic step includes applying a photoresist (not shown) atop the hard mask 20, exposing the photoresist to a desired pattern of radiation, and developing the exposed resist utilizing a conventional resist developer. The etching process comprises drying etching and/or wet chemical etching. Illustrative examples of suitable dry etching processes that can be used in the present disclosure include reactive ion etching, ion beam etching, plasma etching or laser ablation. Typically, a reactive ion etching process or an ion beam etching process is used. The etching process first transfers the pattern from the patterned photoresist to the hard mask 20 and thereafter to the underlying semiconductor layer 18. The patterned photoresist is typically, but not necessarily always, removed after the pattern has been transferred to the hard mask 20. A conventional resist stripping process is used to remove the patterned photoresist from the structure. Alternatively, the semiconductor fins 22, 22′ can also be formed utilizing a conventional sidewall image transfer (SIT) process. In a typical SIT process, a spacer is formed on a dummy mandrel. The dummy mandrel is removed and the remaining spacer is used as a hard mask to etch the semiconductor fins. The spacer is then removed after the semiconductor fins have been formed.

In some embodiments (not shown herein), the hard mask 20 that remains atop the semiconductor fins 22, 22′ can be removed. This particular embodiment allows for fabrication of a tri-gated fully depleted non-planar semiconductor device since the high k dielectric to be subsequently formed would be present on the sidewalls and top surface of each of the semiconductor fins 22, 22′. The removal of the hard mask 20 can be achieved by performing a selective etching process or by utilizing a planarization process such as chemical mechanical planarization.

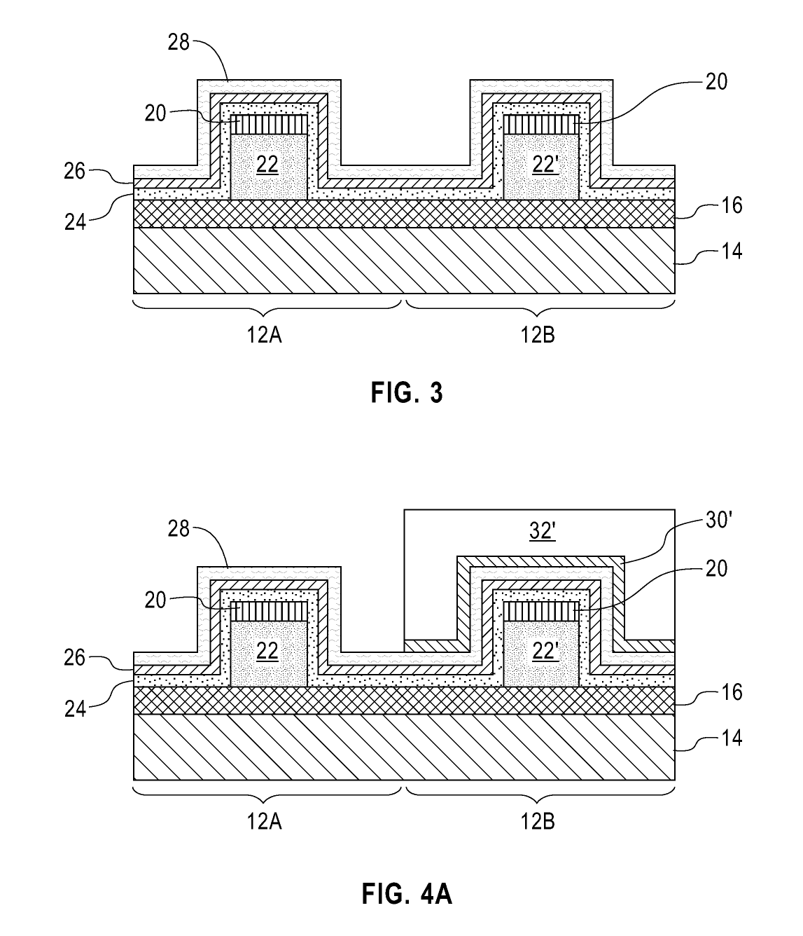

Referring now to FIG. 3, there is shown the structure of FIG. 2 after formation of a high k gate dielectric 24, a first threshold voltage adjusting layer 26, and a first metal gate electrode 28 in both device regions. It is noted that although the drawings and following description describe and illustrate the presence of the first threshold voltage adjusting layer 26, the present disclosure can also be employed when the first threshold voltage adjusting layer 26 is omitted from the structure.

In some embodiments of the present disclosure, an optional chemox layer can be formed on the semiconductor substrate prior to forming the high k gate dielectric. The optional chemox layer is formed utilizing a conventional growing technique that is well known to those skilled in the art including, for example, oxidation or oxynitridation. In some embodiments, the chemox layer is formed by a wet chemical oxidation process. When the substrate is a Si-containing semiconductor, the chemox layer is comprised of silicon oxide, silicon oxynitride or a nitrided silicon oxide. When the semiconductor substrate is other than a Si-containing semiconductor, the chemox layer may comprise a semiconducting oxide, a semiconducting oxynitride or a nitrided semiconducting oxide. The thickness of the chemox layer is typically from 0.5 nm to 1.5 nm, with a thickness from 0.8 nm to 1 nm being more typical. The thickness, however, may be different after processing at higher temperatures, which are usually required during FET or CMOS fabrication.

The high k gate dielectric 24 can be formed by a deposition process such as, for example, chemical vapor deposition (CVD), plasma-assisted CVD, metalorganic chemical vapor deposition (MOCVD), atomic layer deposition (ALD), evaporation, reactive sputtering, chemical solution deposition and other like deposition processes. The high k gate dielectric 24 may also be formed utilizing any combination of the above processes. In some embodiments, the gate dielectric material for semiconductor fin 22 is different from the gate dielectric material for semiconductor fin 22′. Different gate dielectric materials can be formed by utilizing block mask technology.

The high k gate dielectric 24 is comprised of an insulating material having a dielectric constant of greater than silicon oxide, i.e., 4.0 or greater. All dielectric constants mentioned herein are relative to a vacuum unless otherwise noted. Specifically, the high k gate dielectric 24 that can be employed includes, but is not limited to an oxide, nitride, oxynitride and/or silicate including metal silicates and nitrided metal silicates. In one embodiment, it is preferred that the high k gate dielectric 24 is comprised of an oxide such as, for example, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Multilayered stacks of these high k materials can also be employed as the high k gate dielectric 24. Each value of x is independently from 0.5 to 3 and each value of y is independently from 0 to 2. Highly preferred examples of high k gate dielectrics include HfO₂, hafnium silicate and hafnium silicon oxynitride. The physical thickness of the high k gate dielectric 24 may vary, but typically, the high k gate dielectric 24 has a thickness from 0.5 nm to 10 nm, with a thickness from 0.5 nm to about 3 nm being more typical.

After forming the high k gate dielectric 24, a first threshold voltage adjusting layer 26 is formed on the upper surface of the high k gate dielectric 24. The first threshold voltage adjusting layer 26 is comprised of a threshold voltage adjusting material. The term “threshold voltage adjusting material” as used throughout the instant application denotes a material that moves the threshold voltage of a gate stack towards either an nFET or pFET band edge. The first threshold voltage adjusting layer 26 may be composed of an nFET threshold voltage adjusting material or a pFET threshold voltage adjusting material. The type of threshold voltage adjusting material employed as layer 26 in this step is dependent on which conductivity type device, e.g., nFET or pFET, is being fabricated within a specific device region.

One example of an nFET threshold voltage adjusting material that can be used as the first threshold voltage adjusting layer 26 is a rare earth metal-containing material that comprises an oxide or nitride of at least one element from Group IIIB of the Periodic Table of Elements (CAS version) including, for example, La, Ce, Pr, Nd, Pm, Sm, Eu, Ga, Tb, Dy, Ho, Er, Tm, Yb, Lu or mixtures thereof. Preferably, the rare earth metal-containing material comprises an oxide of La, Ce, Y, Sm, Er and/or Tb, with La₂O₃ being more preferred.

The rare earth metal-containing material can be formed utilizing a conventional deposition process including, for example, evaporation, molecular beam deposition, metal-organic chemical vapor deposition (MOCVD), atomic layer deposition (ALD), physical vapor deposition (PVD), ionized PVD and other like deposition processes. In one embodiment of the present disclosure, the rare earth metal-containing material can be formed by placing the structure including the high k gate dielectric into the load-lock of a molecular beam deposition chamber, followed by pumping this chamber down to the range of 10⁻⁵ Torr to 10⁻⁸ Torr. After these steps, the structure is inserted, without breaking vacuum into the growth chamber where the rare earth metal-containing material such as La oxide is deposited by directing atomic/molecular beams of the rare earth metal and oxygen or nitrogen onto the structure's surface. Specifically, because of the low pressure of the chamber, the released atomic/molecular species are beamlike and are not scattered prior to arriving at the structure. A substrate temperature of about 300° C. is used. In the case of La₂O₃ deposition, the La evaporation cell is held in the temperature range of 1400° C. to 1700° C., and a flow rate of 1 sccm to 3 sccm of molecular oxygen is used. Alternatively, atomic or excited oxygen may be used as well, and this can be created by passing the oxygen through a radio frequency source excited in the range of 50 Watts to 600 Watts. During the deposition, the pressure within the chamber can be in the range from 1×10⁻⁵ Torr to 8×10⁻⁵ Torr, and the La oxide growth rate can be in the range from 0.1 nm per minute to 2 nm per minute, with a range from 0.5 nm per minute to 1.5 nm per minute being more typical.

Another example of an nFET threshold voltage adjusting material that can be employed as the first threshold voltage adjusting layer 26 is an alkaline earth metal-containing material that comprises a compound having the formula MAₓ wherein M is an alkaline earth metal (Be, Mg, Ca, Sr, and/or Ba), A is one of O, S and a halide, and x is 1 or 2. Alkaline earth metal-containing compounds that include a mixture of alkaline earth metals and/or a mixture of anions, such as an oxychloride can also be used as an nFET threshold voltage adjusting material. Examples of alkaline earth metal-containing compounds that can be used include, but are not limited to MgO, MgS, MgF₂, MgCl₂, MgBr₂, MgI₂, CaO, CaS, CaF₂, CaCl₂, CaBr₂, Cal₂, SrO, SrS, SrF₂, SrCl₂, SrBr₂, SrI₂, BaO, BaS, BaF₂, BaCl₂, BaBr₂, and Bal₂. In one preferred embodiment of the present disclosure, the alkaline earth metal-containing compound includes Mg. MgO is a highly preferred alkaline earth metal-containing material employed in one embodiment of the present disclosure.

The alkaline earth metal-containing material can be formed utilizing a conventional deposition process including, for example, sputtering from a target, reactive sputtering of an alkaline earth metal under oxygen plasma conditions, electroplating, evaporation, molecular beam deposition, MOCVD, ALD, PVD, ionized PVD and other like deposition processes.

In addition to nFET threshold voltage adjusting materials, the first threshold voltage adjusting layer 26 can alternatively be a pFET threshold voltage adjusting material. Examples of pFET threshold voltage adjusting materials include Al (and its compounds that are non-conductive such as, for example Al₂O₃), Ge (and its compounds that are non-conductive such as, for example GeO₂), and non-conductive compounds of Ti and Ta such as, TiO₂ and Ta₂O₅ respectively.

The pFET threshold voltage adjusting materials can be formed utilizing conventional deposition processes well known to those skilled in the art including, but not limited to chemical vapor deposition (CVD), plasma enhanced chemical vapor deposition (PECVD), chemical solution deposition, atomic layer deposition (ALD), physical vapor deposition (PVD), ionized PVD, sputtering and plating.

Notwithstanding the type of material used as the first threshold voltage adjusting layer 26, the first threshold voltage adjusting layer 26 has a thickness from 0.1 nm to 5.0 nm, with a thickness from 1.0 nm to 3.0 nm being more typical.

In the specific embodiment illustrated in the drawings, the first threshold voltage adjusting layer 26 is comprised of one of the above mentioned pFET threshold voltage adjusting materials.

A first metal gate electrode 28 is then typically formed on the first threshold voltage adjusting layer 26. The first metal gate electrode 28 is comprised of a metal-containing conductive material, including, for example, a metal, a metal alloy, a metal silicide, a metal nitride, a metal carbide or combinations including multilayers thereof. When multilayers are present, a diffusion barrier (not shown), such as TiN or TaN, can be positioned between each of the conductive layers. In one embodiment, the first metal gate electrode 28 is comprised of a p-type metal. In another embodiment, the first metal gate electrode 28 is comprised of an n-type metal.

The first metal gate electrode 28 can be formed utilizing a conventional deposition process including, for example, chemical vapor deposition, plasma enhanced chemical vapor deposition, atomic layer deposition, sputtering, plating, evaporation and any other like deposition process. The thickness of the first metal gate electrode 28 is not critically to the present disclosure. Typically, however, the thickness of the first metal gate electrode 28 is from 1 nm to 20 nm.

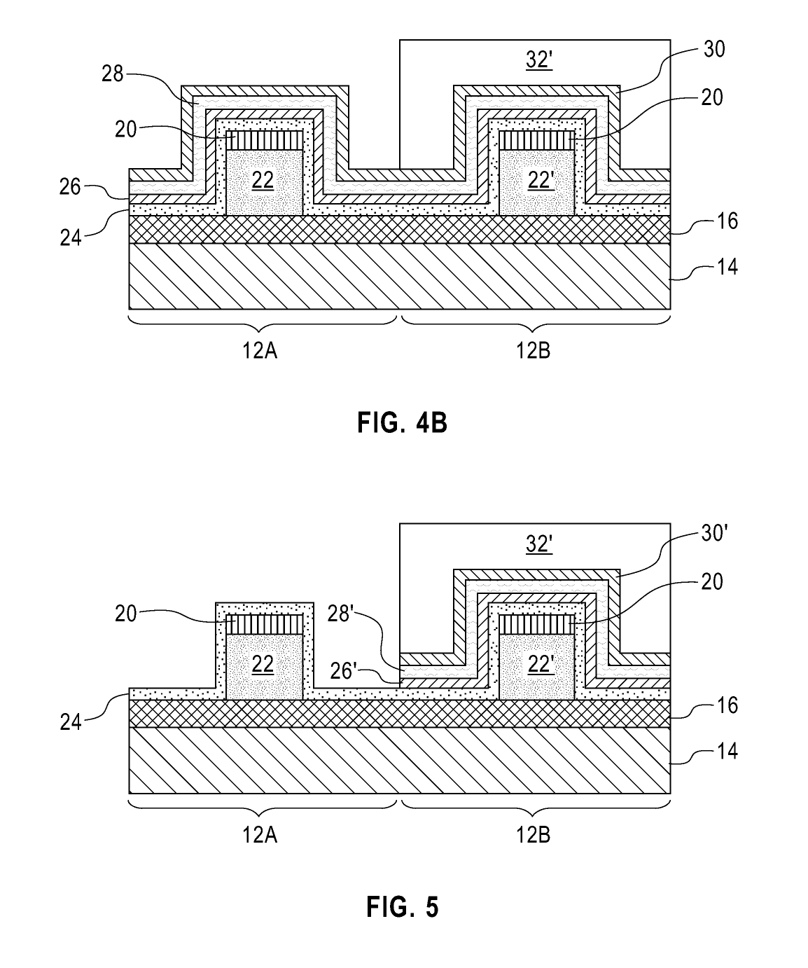

Referring to FIG. 4A and in accordance with an embodiment of the present disclosure, there is shown the structure of FIG. 3 after forming a patterned barrier coating 30′ and an overlying patterned resist 32′ in one of the device regions, while leaving the other device region exposed. It is observed that the patterned barrier coating 30′ and the patterned resist 32′ taken together can be referred to herein as a patterned material stack. In particular, FIG. 4A shows an embodiment in which the patterned barrier coating 30′ and the overlying patterned resist 32′ are formed in the second device region 12B. The structure shown in FIG. 4A is formed by applying a blanket layer of a barrier coating material onto an upper surface of the first metal gate electrode 28 in both device regions.

The blanket layer of barrier coating material can comprise a metal such as, for example Ti or Al, silicon oxide, a silicon based material such as alpha silicon, or a carbon based material such as, for example, alpha carbon or graphene. Multilayers of such materials can also be used as the barrier coating material. In one embodiment, Ti is employed as the barrier coating material. In another embodiment, Al is employed as the barrier coating material. In a further embodiment, alpha silicon is employed as the barrier coating material. It is emphasized that the type of barrier coating material employed is selected such that it is compatible with the overlying resist material and optional antireflective coating to be subsequent formed. Alternatively, and when finFET devices are being formed, the type of barrier coating material employed must have a minimal thickness (typically on the order of 3 nm or less). In addition, the type of barrier coating material that is employed must be able to be selectively removed without damaging the underlying first metal gate electrode 28.

The blanket layer of barrier coating material can be formed utilizing any conventional deposition process including, but not limited to chemical vapor deposition, chemical enhanced vapor deposition, chemical solution deposition, sputtering, electroplating, electroless plating, atomic layer deposition and evaporation. The thickness of the barrier coating material that is formed may vary depending on the type of barrier coating material employed as well as the type of device that is formed. For example, when finFETs are being formed the thickness of the barrier coating material that is formed at this point of the process is typically within a range from 0.2 nm to 3 nm, while when planar devices are being formed, the thickness of the barrier coating material is typically within a range from 0.5 nm to 5 nm.

Next, an optional antireflective coating not shown and a photoresist material is applied atop the blanket layer of barrier coating material. The optional antireflective coating includes any conventional antireflective coating material that is well known to those skilled in the art including organic antireflective coating materials and inorganic antireflective coating materials. When present, the optional antireflective coating material can be formed utilizing a conventional deposition process including, but not limited to spin-on coating, evaporation, chemical solution deposition, and chemical vapor deposition. The photoresist material that can be employed includes any conventional photoresist material that is well known to those skilled in the art including organic photoresist materials and inorganic photoresist materials. The photoresist material can be formed utilizing any conventional deposition process including, for example, spin-on coating, evaporation, chemical solution deposition, chemical vapor deposition and plasma enhanced chemical vapor deposition.

It is observed that the blanket layer of barrier coating material and the blanket layer of photoresist material taken together can be referred to herein as a material stack.

After applying the photoresist material, lithography is used in patterning the photoresist material into patterned resist 32′. The lithography step includes exposing the photoresist material to a predetermined pattern of radiation and developing the exposed resist utilizing a conventional resist developer. After patterning the photoresist material, exposed portions of the barrier coating material are removed providing patterned barrier coating 30′. Specifically, the exposed portions of the barrier coating material are removed utilizing an etching process that removes the exposed barrier coating material selective to the patterned resist, stopping on the underlying first metal gate electrode 28. In one embodiment, dry etching can be employed in removing the exposed portions of the barrier coating material. In another embodiment, chemical wet etching can be employed in removing the exposed portions of the barrier coating material. The barrier coating can be removed selective to TiN by using aqueous ammonium hydroxide or an ammonia peroxide mixture (APM).

After the patterning of the barrier coating material, the patterned resist 32′ located atop the patterned barrier coating 30′ can be removed utilizing a conventional stripping process such as, for example, ashing. The removal of the patterned resist 32′ can occur immediately after forming the patterned barrier coating 30′, or it can remain on the structure during the removal of at least the exposed portion of the first metal gate electrode 28 which is shown in FIG. 5 and described in greater detail herein below. In the embodiment illustrated in the drawings, the patterned resist 32′ remains in the structure and is removed after removing the first metal gate electrode 28 and the first threshold voltage adjusting layer 26 from the first device region 12A.

Referring now to FIG. 4B and in accordance with another embodiment of the present disclosure, there is shown the structure of FIG. 3 after forming a patterned resist 32′ in one device region atop the barrier coating material 30 which remains unpatterned. In this embodiment, a portion of the barrier coating material 30 in the other device region 12 is exposed. In particular, FIG. 4B shows an embodiment in which the patterned resist 32′ is formed atop a portion of the barrier coating material 30 in the second device region 12B, while another portion of the barrier coating material is the first device region 12A is exposed. The structure shown in FIG. 4B is formed as described above for the structure shown in FIG. 4A except that the barrier coating material 30 is not subjected to etching after patterning the photoresist material by lithography.

Referring to FIG. 5, there is the structure of FIG. 4A after removing portions of the first metal gate electrode 28 and the underlying first threshold voltage adjusting layer 26 in one of the device regions that is not protected by at least the pattered barrier coating 30′. It is observed that in FIG. 5 and in the remaining drawings, reference numeral 28′ denotes the patterned first metal gate electrode and reference numeral 26′ denotes the patterned first threshold voltage adjusting layer. After removing portions of the first metal gate electrode 28 and the underlying first threshold voltage adjusting layer 26 in the exposed device region not including at least the patterned barrier coating 30′, portions of the high k gate dielectric 24 are now exposed. FIG. 5 also shows the structure of FIG. 4B after etching exposed portions of the barrier coating material 30, underlying first metal gate electrode 28, and underlying first threshold voltage adjusting layer 26 in the exposed device region not including the patterned resist 32′.

The removal of the exposed portion of the first metal gate electrode 28 can be performed utilizing a dry etching process or a chemical wet etching process. In one embodiment, reactive ion etching or using APM can be used to remove the exposed portion of the first metal gate electrode 28. In embodiments in which the non-protected portion of the barrier coating material needs to be removed from the structure, see, for example, the structure of FIG. 4B, an etching process is used to removed the same. The etching process used in removing the exposed portion of the barrier coating is selective to the neighboring material layers. In one embodiment, aqueous ammonia hydroxide or an ammonium peroxide mixture (APM) can be used in removing the exposed portion of the barrier coating material 30. In some embodiments, removal of the barrier coating material 30 and the first gate electrode 28 not protected by patterned resist 32′ is performed utilizing a two step etching process. While in other embodiments, a single etch can be used to remove both the barrier coating material 30 and the first gate electrode 28 not protected by patterned resist 32′.

In one embodiment, the removal of the underlying portion of the first threshold voltage adjusting layer 26 can occur simultaneously with the removal of the overlying portion of the first metal gate electrode 28 utilizing a same etching step. In another embodiment, the removal of the underlying portion of the first threshold voltage adjusting layer 26 can occur in a different step than the removal of the overlying portion of the first metal gate electrode 28 utilizing another etching process (dry etching or wet etching) that selectively removes the exposed portions of the first threshold voltage adjusting materials.

At this point of the instant process, the patterned barrier coating 30′ and, if not previously removed, the overlying patterned resist 32′ can be removed from the structure. If present, the patterned resist 32′ is removed utilizing a conventional stripping process as mentioned above. The patterned barrier coating 30′ can be removed utilizing an etching step that is selective in removing the barrier coating material relative to the neighboring material layers. In some embodiments, and as mentioned above, aqueous ammonia hydroxide or an ammonia peroxide mixture (APM) can be used. In some embodiments (not shown), the patterned barrier coating 30′ can remain within the structure and provide a barrier between the patterned first metal gate electrode 28′ and the second metal gate electrode 34 to be subsequently formed.

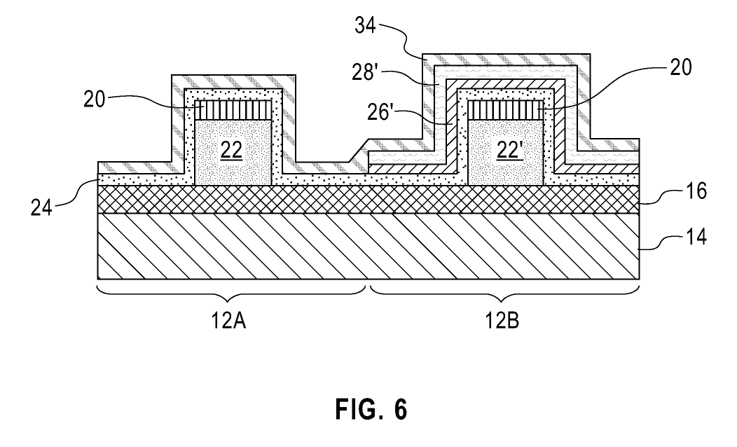

Referring now to FIG. 6, there is shown the structure of FIG. 5 after forming at least a second metal gate electrode 34 in both device regions. In some embodiments, not shown, a second threshold voltage adjusting layer is formed selectively on the exposed surface of the high k gate dielectric in the device region not including the first threshold voltage adjusting layer. In such embodiments, the second threshold voltage adjusting layer would be located between the high k gate dielectric 24 and the second metal gate electrode 34. In the aforementioned embodiment, the second threshold voltage adjusting layer would be comprised of an opposite threshold voltage type material as compared to the material of the first threshold voltage adjusting layer, i.e., the other of a pFET threshold voltage adjusting material or an nFET threshold voltage adjusting material not used as the material for the first threshold voltage adjusting layer. In such embodiments, block mask technology including the use of the above barrier coating material can be used to form the optional second threshold voltage adjusting layer in the device region not including the first threshold voltage adjusting layer.

In other embodiments, also not shown, an optional second threshold voltage layer can be formed in both device regions and can remain in both devices. In such embodiments, the second threshold voltage adjusting layer would be located between the high k gate dielectric 24 and the second metal gate electrode 34 in one device region, and between the patterned first metal gate electrode 28′ and the second metal gate electrode 34 in the other device region. In the aforementioned embodiment, the second threshold voltage adjusting layer would be comprised of an opposite threshold voltage type material as compared to the material of the first threshold voltage adjusting layer, i.e., the other of a pFET threshold voltage adjusting material or an nFET threshold voltage adjusting material not used as the material for the first threshold voltage adjusting layer.

The second metal gate electrode 34 may be comprised of the same or different, typically the same, metal-containing conductive material as the first metal gate electrode 28. The second metal gate electrode 34 can be formed utilizing one of the above mentioned techniques mentioned in forming the first metal gate electrode 28 and the thickness of the second metal gate electrode 34 can be in the thickness regime mentioned above for the first metal gate electrode 28.

After forming the second metal gate electrode 34, conventional processing steps can be performed including, for example, formation of source/drain regions, formation of metal semiconductor alloy contacts, formation of raised source/drain regions, merging of semiconductor fins, and formation of an interlevel dielectric material on the structure shown in FIG. 6. In some embodiments, and after forming the second metal gate electrode 34, a Si-containing electrode, such as doped Si or doped SiGe, can be formed atop either the first metal gate electrode 28 or the second metal gate electrode 34, or both the first and second metal gate electrodes. When a Si-containing electrode is formed, the Si-containing electrode can be formed utilizing conventional techniques well known to those skilled in the art.

It is observed that although the above embodiment has been illustrated in respect to non-planar fully depleted semiconductor structures, the above processing steps can also be employed in forming a planar semiconductor substrate utilizing any conventional CMOS or finFET processing flow. When planar semiconductor devices and other non-planar semiconductor devices are formed, an optional chemox layer as described above can be formed on the semiconductor substrate prior to forming the high k gate dielectric. The optional chemox layer is formed utilizing a conventional growing technique that is well known to those skilled in the art including, for example, oxidation or oxynitridation. In some embodiments, the chemox layer is formed by a wet chemical oxidation process. When the substrate is a Si-containing semiconductor, the chemox layer is comprised of silicon oxide, silicon oxynitride or a nitrided silicon oxide. When the semiconductor substrate is other than a Si-containing semiconductor, the chemox layer may comprise a semiconducting oxide, a semiconducting oxynitride or a nitrided semiconducting oxide. The thickness of the chemox layer is typically from 0.5 nm to 1.5 nm, with a thickness from 0.8 nm to 1 nm being more typical. The thickness, however, may be different after processing at higher temperatures, which are usually required during FET or CMOS fabrication.

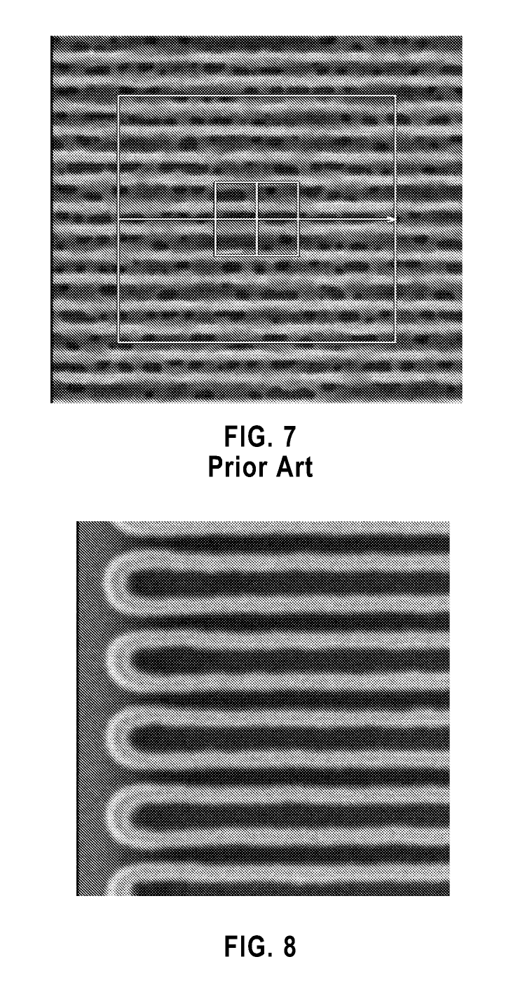

Reference is now made to FIGS. 7 and 8 which compare a high k/metal gate electrode that has been processed utilizing a prior art processing flow, i.e., without the use of the barrier coating disclosed herein (see, FIG. 7), and a high k/metal gate stack that has been processed utilizing the processing flow of the present disclosure, i.e., with the use of the barrier coating disclosed herein (See FIG. 8). Specifically, it is clearly seen that the structure shown in FIG. 7 includes resist residues on the patterned high/metal gate stacks, while the structure shown in FIG. 8 includes patterned high k/metal gate stacks in which resist residues is substantially eliminated. The elimination of the resist during the resist patterning prevents any unwanted micro-masking made by the resist residue during the metal gate electrode etch resulting in undesirable device shorts.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method of forming at least one patterned high k/metal gate stack comprising:
forming a gate dielectric having a dielectric constant that is greater than silicon oxide on at least one surface of a semiconductor substrate;
forming a metal gate electrode atop the gate dielectric;
forming a material stack including, from bottom to top, a barrier coating material and a photoresist material atop the metal gate electrode;
patterning at least the photoresist material of the material stack providing at least a patterned resist atop the metal gate electrode; and
removing at least the metal gate electrode, not protected by at least the patterned resist, providing a patterned metal gate electrode.

2. The method of claim 1 wherein the semiconductor substrate has a planar upper surface.

3. The method of claim 1 wherein the semiconductor substrate includes at least one semiconductor fin and said gate dielectric is formed on at least sidewalls of said at least one semiconductor fin.

4. The method of claim 1 wherein said forming the material stack includes selecting one of Al, Ti, silicon oxide, alpha silicon, alpha carbon and graphene as said barrier coating material.

5. The method of claim 1 wherein said patterning further includes patterning the barrier coating material to provide a patterned material stack including said patterned resist and a patterned barrier coating.

6. The method of claim 1 wherein said removing at least the metal gate electrode further includes removing an overlying portion of said barrier coating material.

7. A method of forming a complementary metal oxide semiconductor structure comprising:
providing a semiconductor substrate having a first device region and a second device region;
forming a gate dielectric having a dielectric constant that is greater than silicon oxide on at least one surface of the semiconductor substrate in both device regions;
forming a first metal gate electrode atop the gate dielectric in both device regions;
forming a material stack including, from bottom to top, a barrier coating material and a photoresist material atop the first metal gate electrode;
patterning at least the photoresist material of the material stack to provide a patterned resist atop the first metal gate electrode in one of the device regions;
removing at least the first metal gate electrode in the other device region, not protected by at least the patterned resist, providing a patterned first metal gate electrode in the one device region; and
forming a second metal gate electrode in both device regions, wherein a first portion of the second metal gate electrode is present atop the first metal gate electrode in the one device region and a second portion of the second metal gate electrode is present atop the gate dielectric in the other device region.

8. The method of claim 7 further comprising forming a first threshold voltage adjusting layer between said gate dielectric and said first metal gate electrode.

9. The method of claim 7 wherein said forming the material stack includes selecting one of Al, Ti, silicon oxide, alpha silicon, alpha carbon and graphene as said barrier coating material.

10. The method of claim 7 wherein said patterning further includes patterning the barrier coating material to provide a patterned material stack including said patterned resist and a patterned barrier coating.

11. The method of claim 7 wherein said removing at least the metal gate electrode further includes removing an overlying portion of said barrier coating material.

12. The method of claim 8 further comprising forming a second threshold voltage adjusting layer between said gate dielectric and said second metal gate electrode in the one device region, wherein the first threshold voltage adjusting layer is an nFET or a pFET threshold voltage adjusting material, and the second threshold voltage adjusting layer is the other of the nFET or the pFET threshold voltage adjusting material not used as the first threshold voltage adjusting layer.

13. A method of forming a complementary metal oxide semiconductor finFET structure comprising:
providing a semiconductor substrate having a first device region and a second device region;
forming at least one semiconductor fin in each of the device regions;
forming a gate dielectric having a dielectric constant that is greater than silicon oxide on at least sidewalls of each semiconductor fin in both device regions;
forming a first metal gate electrode atop the gate dielectric in both device regions;
forming a material stack including, from bottom to top, a barrier coating material and a photoresist atop the first metal gate electrode;
patterning at least the photoresist material of the material stack providing a patterned resist atop the first metal gate electrode in one of the device regions;
removing the first metal gate electrode in the other device region, not protected by at least the patterned resist, providing a patterned first metal gate electrode in the one device region; and
forming a second metal gate electrode in both device regions, wherein a first portion of the second metal gate electrode is present atop the first metal gate electrode in the one device region and a second portion of the second metal gate electrode is present atop the gate dielectric in the other device region.

14. The method of claim 13 further comprising forming a first threshold voltage adjusting layer between said gate dielectric and said first metal gate electrode.

15. The method of claim 13 wherein said forming the material stack includes selecting one of Al, Ti, silicon oxide, alpha silicon, alpha carbon and graphene as said barrier coating material.

16. The method of claim 13 wherein said patterning further includes patterning the barrier coating material to provide a patterned material stack including said patterned resist and a patterned barrier coating.

17. The method of claim 13 wherein said removing at least the metal gate electrode further includes removing an overlying portion of said barrier coating material.

18. The method of claim 14 further comprising forming a second threshold voltage adjusting layer between said gate dielectric and said second metal gate electrode in the one device region, wherein the first threshold voltage adjusting layer is an nFET or a pFET threshold voltage adjusting material, and the second threshold voltage adjusting layer is the other of the nFET or the pFET threshold voltage adjusting material not used as the first threshold voltage adjusting layer.

19. A semiconductor structure comprising:
a semiconductor substrate having at least one patterned gate stack located on a surface thereof, wherein said at least one patterned gate stack includes, from bottom to top, a high k gate dielectric and a metal gate electrode, and wherein said at least one patterned gate stack is free of resist residues.

20. The semiconductor structure of claim 19 further comprising a threshold voltage adjusting layer located between the high k gate dielectric and the metal gate electrode.

21. The semiconductor structure of claim 20 wherein said threshold voltage adjusting layer includes an nFET threshold voltage adjusting material, wherein said nFET threshold voltage adjusting material is a rare earth metal-containing material comprising an oxide or nitride of at least one element from Group IIIB of the Periodic Table of Elements or an alkaline earth metal-containing material having the formula MAₓ wherein M is an alkaline metal, A is one of O, S and a halide, and x is 1 or 2.

22. The semiconductor structure of claim 20 wherein said threshold voltage adjusting layer is a pFET threshold voltage adjusting material selected from Al, non conductive compounds of Al, Ge, non-conductive compounds of Ge, non-conductive compounds of Ti and non-conductive compounds of Ta.

23. The semiconductor structure of claim 19 wherein said semiconductor substrate includes at least one semiconductor fin, and said high k gate dielectric is located on at least sidewalls of said at least one semiconductor fin.

24. The semiconductor structure of claim 19 wherein the semiconductor substrate includes a first device region and a second device region, and wherein the at least one patterned gate stack comprises at least one first patterned gate stack including, from bottom to top, a first portion of the high k gate dielectric, a first metal gate electrode, and a first portion of a second metal gate electrode present in one of the device regions, and at least one second patterned gate stack including, from bottom to top, a second portion of the gate dielectric material, and a second portion of the second metal gate electrode present in the other device region, and further wherein each of the patterned gate stacks is free of resist residues.

25. The semiconductor structure of claim 24 wherein a first threshold voltage adjusting layer is present between the first portion of the high k gate dielectric and the first metal gate electrode, and a second threshold voltage adjusting layer is between the second portion of the high k gate dielectric and the second portion of the second metal gate electrode, wherein said first threshold voltage adjusting layer is an nFET or pFET threshold voltage adjusting material, and the second threshold voltage adjusting layer is the other of the nFET or the pFET threshold voltage adjusting material not used as the first threshold voltage adjusting layer.

26. The semiconductor structure of claim 25 wherein said first threshold voltage adjusting layer is pFET threshold voltage adjusting material and the second threshold voltage adjusting layer is an nFET threshold voltage adjusting material.

27. The semiconductor of claim 20 further comprising a patterned barrier coating atop said metal gate electrode.
